(19) United States
(12) Patent Application Publication
(10) Pub. No.: US 2009/0034316 A1
(43) Pub. Date: Feb. 5, 2009

(54) MEMORY

(75) Inventor: Kouichi Yamada, Hashima-gun (JP)

Correspondence Address: MCDERMOTT WILL & EMERY LLP, 600 13TH STREET, N.W., WASHINGTON, DC, 20005-3096, US

(73) Assignee: SANYO ELECTRIC CO. LTD.

(21) Appl. No.: 12/183,785

(22) Filed: Jul. 31, 2008

(30) Foreign Application Priority Data
Jul. 31, 2007 (JP) JP2007-198330
Sep. 12, 2007 (JP) JP2007-236914

(51) Int. Cl. G11C 17/00; G11C 17/06

(52) U.S. Cl. 365/104; 365/94; 365/105

(57) ABSTRACT

A memory includes a plurality of word lines, a plurality of bit lines so arranged as to intersect with the plurality of word lines, a plurality of memory cells arranged on positions where the word lines and the bit lines intersect with each other respectively and selection circuits connected to the bit lines, wherein the current driving ability of the selection circuits is different depending on positions where the bit lines are arranged.

### CROSS-REFERENCE TO RELATED APPLICATIONS

The priority application number JP2007-198330, Memory, Jul. 31, 2007, Kouichi Yamada, JP2007-236914, Memory, Sep. 12, 2007, Kouichi Yamada, upon which this patent application is based is hereby incorporated by reference.

### BACKGROUND OF THE INVENTION

1. Field of the Invention

The present invention relates to a memory, and more particularly, it relates to a memory such as a mask ROM.

2. Description of the Background Art

A crosspoint mask ROM (hereinafter referred to as a crosspoint diode ROM) having a plurality of memory cells, each including a diode, arranged in the form of a matrix is generally known as an exemplary memory. The conventional exemplary crosspoint diode ROM comprises a plurality of word lines, a plurality of bit lines arranged adjacent to each other at prescribed intervals, intersecting with the plurality of word lines, a plurality of memory cells each including a diode arranged on an intersectional position between the word line and the bit line and a sense amplifier (data determination circuit) for determining data read from the selected memory cell, connected to the bit lines. In this crosspoint diode ROM, the sense amplifier senses a current flowing from the sense amplifier to the word lines through the bit lines and the diodes, to determine data of the memory cells. A cathode of the diode including the memory cell connected to each word line is formed by a common impurity region.

In the conventional crosspoint diode ROM, however, the distance of the impurity region through which a current flowing each bit line to the corresponding word line passes is different for each bit line, whereby a cell current is large when the distance of the impurity region between the bit line and the end of the corresponding word line is short while a cell current is small when the distance is long. Thus, a large current flows in the bit line when the distance of the impurity region between the bit line and the end of the corresponding word line is short, and hence current consumption (power consumption) is disadvantageously increased as a whole.

### SUMMARY OF THE INVENTION

A memory according to a first aspect of the present invention comprises a plurality of word lines, a plurality of bit lines so arranged as to intersect with the plurality of word lines, a plurality of memory cells arranged on positions where the word lines and the bit lines intersect with each other respectively, and selection circuits connected to the bit lines, wherein the current driving ability of the selection circuits is different depending on positions where the bit lines are arranged.

A memory according to a second aspect of the present invention comprises a plurality of word lines, a plurality of bit lines so arranged as to intersect with the plurality of word lines, first transistors connected to the plurality of word lines respectively and entering ON-states when corresponding the word lines are selected, a plurality of memory cells including diodes having cathodes connected to either source regions or drain regions of the first transistors respectively, a source line connected to either the source regions or the drain regions of the first transistors, and a data determination circuit for determining data read from selected the memory cell, connected to the source line, wherein the driving ability of the bit lines is different depending on positions where the bit lines are arranged.

A memory according to a third aspect of the present invention comprises a plurality of word lines, a plurality of bit lines so arranged as to intersect with the plurality of word lines, a plurality of memory cells arranged on positions where the word lines and the bit lines intersect with each other respectively, and a plurality of switching elements connected to the plurality of bit lines respectively, wherein the driving ability of the switching elements is different depending on positions where the bit lines are arranged.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram showing a structure of a crosspoint diode ROM according to a first embodiment of the present invention;

FIG. 2 is a plane layout diagram showing the structure of the crosspoint diode ROM according to the first embodiment of the present invention;

FIG. 3 is a sectional view taken along the line 100-100 in FIG. 2;

FIG. 4 is a plane layout diagram showing a structure of a crosspoint diode ROM according to a second embodiment of the present invention;

FIG. 5 is a circuit diagram showing a structure of a crosspoint diode ROM according to a third embodiment of the present invention;

FIG. 6 is a plane layout diagram showing the structure of the crosspoint diode ROM according to the third embodiment of the present invention;

FIG. 7 is a sectional view taken along the line 200-200 in FIG. 6; and

FIG. 8 is a plane layout diagram showing a structure of a crosspoint diode ROM according to a fourth embodiment of the present invention.

### DESCRIPTION OF THE PREFERRED EMBODIMENTS

Embodiments of the present invention will be hereinafter described with reference to the drawings.

### First Embodiment

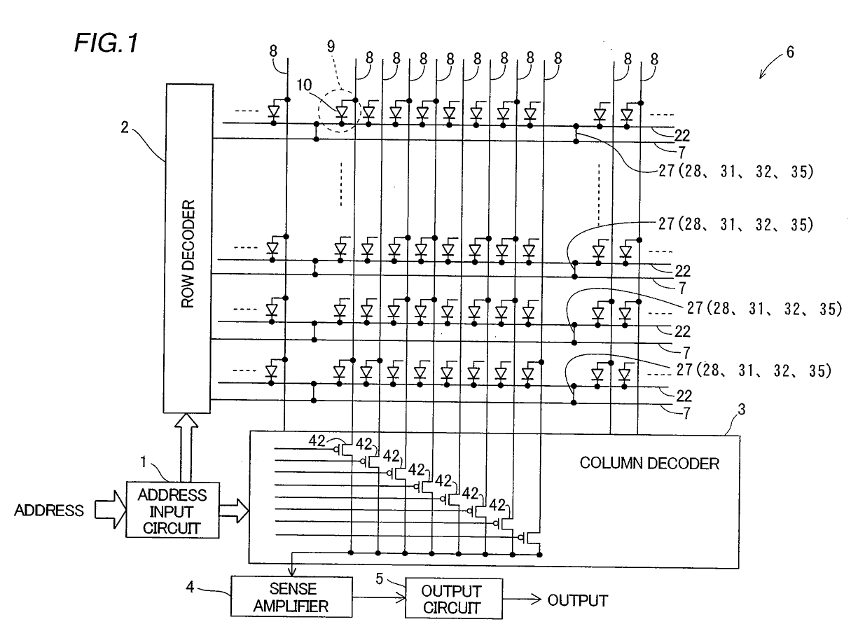

As shown in FIG. 1, the mask ROM according to the first embodiment comprises an address input circuit 1, a row decoder 2, a column decoder 3, a sense amplifier 4, an output circuit 5 and a memory cell array region 6. The address input circuit 1 is so formed as to output address data to the row decoder 2 and the column decoder 3 by externally receiving a prescribed address. Word lines 7 are connected to the row decoder 2. When receiving address data from the address input circuit 1, the row decoder 2 selects a word line 7 corresponding to the received address data and brings the potential of this word line 7 into a low level (GND=0 V). Thus, the potentials of the remaining word lines 7 are set to a high level (Vcc).

A plurality of bit lines 8 arranged to intersect with the word lines 7 are connected to the column decoder 3. When receiving address data from the address input circuit 1, the column decoder 3 selects a bit line 8 corresponding to the received address data and connects the selected bit line 8 with the sense amplifier 4 through a p-type transistor 42 described later. The transistor 42 is an example of the “selection circuit” and the “switching element” in the present invention. The sense amplifier 4 senses a current flowing in the bit line 8 selected by the column decoder 3 for outputting a high-level signal when the quantity of the current flowing in the selected bit line 8 is in excess of a prescribed level while outputting a low-level signal when the quantity of the current flowing in the selected bit line 8 is less than the prescribed level. The output circuit 5 is so formed as to output a signal when receiving an output from the sense amplifier 4.

A plurality of memory cells 9 are arranged on the memory cell array region 6 in the form of a matrix. The plurality of memory cells 9 are arranged on the intersections between the plurality of word lines 7 and the plurality of bit lines 8 arranged to intersect with each other respectively. Thus, the mask ROM according to the first embodiment is constituted as a crosspoint mask ROM. The memory cells 9 provided on the memory cell array region 6 include those having diodes 10 whose anodes are connected to the corresponding bit lines 8 and those having diodes 10 whose anodes are not connected to the corresponding bit lines 8.

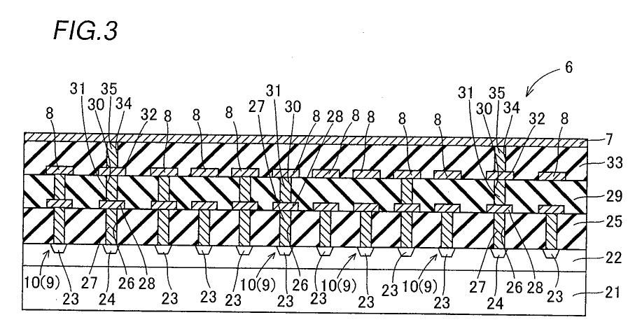

In the memory cell array region 6, a plurality of n-type impurity regions 22 are formed on an upper surface of a p-type silicon substrate 21 along an extensional direction of the word lines 7, as shown in FIG. 3. The impurity regions 22 are examples of the “impurity region” in the present invention. The plurality of n-type impurity regions 22 are formed along a direction perpendicular to the extensional direction thereof at prescribed intervals.

A plurality of p-type impurity regions 23 are formed in each n-type impurity region 22 along the extensional direction of the n-type impurity region 22 at prescribed intervals. Each p-type impurity region 23 and the corresponding impurity region 22 form the diode 10 of each memory cell 9. Thus, each impurity region 22 functions as a common cathode of the plurality of diodes 10, while the corresponding impurity regions 23 function as the anodes of the corresponding diodes 10. In each n-type impurity region 22, further, an n-type contact region 24 is formed every eight impurity regions 23. These n-type contact regions 24 are provided for reducing contact resistance of first-layer plugs 27 described later with respect to the impurity regions 22 of the silicon substrate 21.

A first interlayer dielectric film 25 is provided to cover an upper surface of the silicon substrate 21. Contact holes 26 are provided in regions of the first interlayer dielectric film 25 corresponding to the impurity regions 23 and the contact regions 24 respectively. The first-layer plugs 27 of W (tungsten) are embedded in the contact holes 26. Thus, the first-layer plugs 27 are connected to the impurity regions 23 and the contact regions 24 respectively.

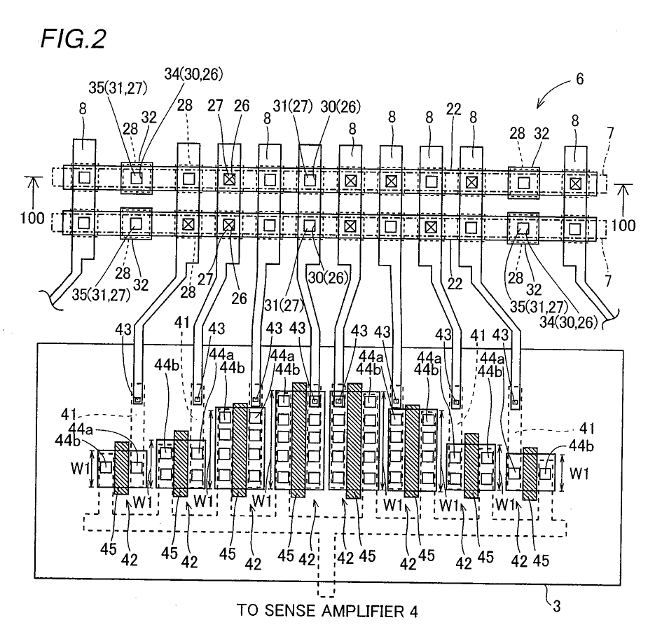

First pad layers 28 made of Al are provided on the first interlayer dielectric film 25, to be connected to the first-layer plugs 27. These pad layers 28 are substantially squared in plan view (see FIG. 2). A second interlayer dielectric film 29 is provided on the first interlayer dielectric film 25, to cover the first pad layers 28. Contact holes 30 are formed in regions of the second interlayer dielectric film 29 corresponding to the first pad layers 28. Second-layer plugs 31 of W are embedded in the contact holes 30. The plurality of bit lines 8 made of Al are formed on the second interlayer dielectric film 29 at prescribed intervals. As shown in FIG. 2, the bit lines 8 are so formed as to extend perpendicularly to the extensional direction of the impurity regions 22, and arranged to intersect with the impurity regions 22 on regions corresponding to the diodes 10 of the memory cells 9 (see FIG. 1).

The mask ROM switches data of the memory cells 9 depending on whether or not the contact holes 30 are formed between the first pad layers 28 and the bit lines 8 in correspondence to the diodes 10 of the memory cells 9. When a contact hole 30 is formed in correspondence to the diode 10 of any memory cell 9 so that the corresponding bit line 8 and the impurity region 23 constituting the diode 10 of this memory cell 9 are connected with each other through the plug 31 embedded in this contact hole 30, the corresponding first pad layer 28 and the corresponding first-layer plug 27, the mask ROM sets the data of this memory cell 9 to “1”. When no contact hole 30 is formed in correspondence to the diode 10 of any memory cell 9 so that the diode 10 of this memory cell 9 and the corresponding bit line 8 are not connected with each other, on the other hand, the mask ROM sets the data of this memory cell 9 to “0”.

Second pad layers 32 made of Al are formed on regions of the second interlayer dielectric film 29 corresponding to the second-layer plugs 31 respectively. The second pad layers 32 are substantially squared in plan view (see FIG. 2). A third interlayer dielectric film 33 is provided on the second interlayer dielectric film 29, to cover the bit lines 8 and the second pad layers 32. Contact holes 34 are provided in regions of the third interlayer dielectric film 33 corresponding to the second pad layers 32, and third-layer plugs 35 made of W are embedded in these contact holes 34. Thus, the third-layer plugs 35 are connected to the second pad layers 32.

The word lines 7 made of Al are formed on the third interlayer dielectric film 33, to extend along the extensional direction of the impurity regions 22. The plurality of word lines 7, provided along the direction perpendicular to the extensional direction at prescribed intervals, are arranged above the impurity regions 22 respectively. These word lines 7 are connected to the third-layer plugs 35. According to the first embodiment, the word lines 7 and the impurity regions 22 are connected with each other every eight memory cells (at prescribed intervals) through the third-layer plugs 35, the second pad layers 32, the second-layer plugs 31, the first pad layers 28 and the first-layer plugs 27. The plugs 35, the pad layers 32, the plugs 31, the pad layers 28 and the plugs 27 are examples of the “first metal wire” in the present invention. When selecting any word line 7 corresponding to address data received in the row decoder 2 (see FIG. 1), the mask ROM according to the first embodiment brings the potential of the selected word line 7 into the low level (GND) while setting the potentials of the remaining word lines 7 to the high level (Vcc).

The distances of the impurity region 22 from the cathodes of the diodes 10 under the bit lines 8 arranged on the ends in each eight bit lines 8 connected to the corresponding eight memory cells 9 to the word line 7 are shorter than the distances of the impurity region 22 from the cathodes of the diodes 10 under the bit lines 8 arranged on the central portion in each eight bit lines 8 to the word line 7. As the distances of the impurity region 22 from the cathodes of the diodes 10 to the word line 7 are longer, an electric resistance from the cathodes to the word line 7 is increased.

As shown in FIG. 2, a plurality of the bit lines 8 have first ends connected to the transistors 42 through metal wires 41 in the column decoder 3 respectively. The bit lines 8 and the metal wires 41 are electrically connected to each other through contact portions 43. The metal wires 41 and either the source regions or the drain regions of the transistors 42 are electrically connected to each other through contact portions 44a. Either the source regions or the drain regions of the transistors 42 are connected to the sense amplifier 4 through contact portions 44b. According to the first embodiment, gate widths W1 of the transistors 42 connected to the bit lines 8 arranged on the central portion in each eight bit lines are formed to be smaller than gate widths W1 of the transistors 42 connected to the bit lines 8 arranged on the ends in each eight bit lines 8. Thus, the current driving ability of the transistors 42 connected to the bit lines 8 arranged on the ends in each eight bit lines is smaller than the current driving ability of the transistors 42 connected to the bit lines 8 arranged on the central portion of the eight bit lines 8 due to the smaller gate widths W1.

More specifically, according to the first embodiment, the gate widths W1 of the transistors 42 connected to the bit lines 8 are gradually reduced from the bit lines 8 arranged on the central portion in each eight bit lines 8 toward the bit lines 8 arranged on the ends. Thus, the current driving ability of the transistors 42 connected to the bit lines 8 is gradually reduced from the bit lines 8 arranged on the central portion to the bit lines 8 arranged on the ends.

Operations of the mask ROM according to the first embodiment will be now described with reference to FIGS. 1 and 2.

First, the address input circuit 1 receives a prescribed address. Thus, the address input circuit 1 outputs address data responsive to the received address to the row decoder 2 and the column decoder 3 respectively. The row decoder 2 decodes the address data, thereby selecting a prescribed word line 7 corresponding thereto. The mask ROM brings the potential of the selected word line 7 to the low level (GND), while setting the potentials of the remaining word lines 7 to the high level (Vcc).

On the other hand, the column decoder 3 receiving the address data from the address input circuit 1 selects a prescribed bit line 8 corresponding to the received address data, and connects the selected bit line 8 to the sense amplifier 4. Then, the sense amplifier 4 supplies a potential close to Vcc to the selected bit line 8. If the anode of the diode 10 of the selected memory cell 9 located on the intersection between the selected word line 7 and the selected bit line 8 is linked to the bit line 8, a current flows from the sense amplifier 4 to the word line 7 through the bit line 8 and the diode 10. At this time, the sense amplifier 4 senses that the quantity of the current flowing in the bit line 8 is in excess of the prescribed level, and outputs a high-level signal. The output circuit 5 receiving this output signal from the sense amplifier 4 outputs a high-level signal.

If the anode of the diode 10 of the selected memory cell 9 located on the intersection between the selected word line 7 and the selected bit line 8 is not linked to the bit line 8, on the other hand, no current flows from the bit line 8 to the word line 7. In this case, the sense amplifier 4 senses that no current flows to the word line 7, and outputs a low-level signal. The output circuit 5 receiving this output signal from the sense amplifier 4 outputs a low-level signal.

According to the first embodiment, as hereinabove described, in the transistors 42 connected to each eight bit lines 8 connected to the eight memory cells 9, the current driving ability of the transistors 42 connected to the bit lines 8 arranged on the ends in the eight bit lines 8 is rendered low while the current driving ability of the transistors 42 connected to the bit lines 8 arranged on the central portion in the eight bit lines 8 is rendered high, whereby the low current driving ability of the transistors 42 can inhibit a large current from flowing in the wires connecting the bit lines 8 and the sense amplifier 4 even when the distances of the impurity regions 22 between the word lines 7 and the diodes 10 are short. Thus, increase in current consumption (power consumption) can be suppressed.

According to the first embodiment, as hereinabove described, the current driving ability of the transistors 42 connected to the bit lines 8 is reduced from the bit lines 8 arranged on the central portion toward the bit lines 8 arranged on the ends in each eight bit lines 8, whereby the current driving ability of the transistors 42 is gradually reduced from the central portion with a large resistance due to the longer distances of the impurity region 22 between the word line 7 and the cathodes of the diodes 10 toward the ends with a small resistance, and hence the difference between the quantities of current flowing in the respective bit lines 8 can be reduced. Thus, the cell current flowing in the memory cell array regions 6 can be reduced as a whole.

According to the first embodiment, as hereinabove described, the gate widths W1 of the transistors 42 connected to the bit lines 8 arranged on the ends in each eight bit lines 8 are smaller than the gate widths W1 of the transistors 42 connected to the bit lines 8 arranged on the central portion, whereby the current driving ability of the transistors 42 connected to the bit lines 8 arranged on the ends in a plurality of the bit lines 8 can be easily rendered smaller than the current driving ability of the transistors 42 connected to the bit lines 8 arranged on the central portion since an electric resistance is larger when the gate width W1 is small.

According to the first embodiment, as hereinabove described, the gate widths W1 of the transistors 42 connected to the bit lines 8 are gradually reduced from the bit lines 8 arranged on the central portion toward the bit lines 8 arranged on the end in each eight bit lines 8, whereby the gate widths W1 can be gradually reduced as the distances of the impurity region 22 between the word line 7 and the cathodes of the diodes 10 are reduced (toward the bit lines 8 arranged on the ends). Thus, an electric resistance can be increased as the gate widths W1 of the transistors 42 are gradually reduced, and hence the current driving ability of the transistors 42 connected to the bit lines 8 can be gradually reduced from the bit lines 8 arranged on the central portion toward the bit lines 8 arranged on the ends.

### Second Embodiment

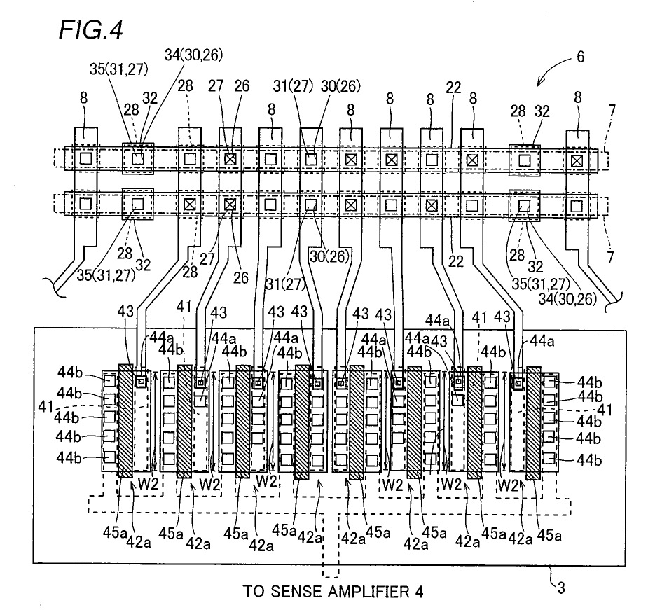

In a crosspoint diode ROM according to a second embodiment, a plurality of bit lines 8 have first ends connected to transistors 42a through metal wires 41 in a column decoder 3 respectively as shown in FIG. 4, similarly to the aforementioned first embodiment. The transistors 42a all have the same gate widths W2 dissimilarly to the first embodiment. The metal wires 41 and the transistors 42a are connected to each other through contact portions 43.

According to the second embodiment, in the number of contact portions 44a connecting either the source regions or the drain regions of the transistors 42a and the metal wires 41, the number of the contact portions 44a connecting either the source regions or the drain regions of the transistors 42a connected to the bit lines 8 arranged on the ends in each eight bit lines 8 and the metal wires 41 is smaller than the number of the contact portions 44a connecting either the source regions or the drain regions of the transistors 42a connected to the bit lines 8 arranged on the central portion and the metal wires 41.

More specifically, the number of the contact portions 44a connecting either the source regions or the drain regions of the transistors 42a and the metal wires 41 is gradually reduced from the bit lines 8 arranged on the central portion toward the bit lines 8 arranged on the ends in each eight bit lines 8.

The remaining structure of the second embodiment is similar to that of the aforementioned first embodiment.

According to the second embodiment, as hereinabove described, in the number of the contact portions 44a connecting either the source regions or the drain regions of the transistors 42a and the metal wires 41, the number of the contact portions 44a connecting either the source regions or the drain regions of the transistors 42a connected to the bit lines 8 arranged on the ends in each eight bit lines 8 and the metal wires 41 is smaller than the number of the contact portions 44a connecting either the source regions or the drain regions of the transistors 42a connected to the bit lines 8 arranged on the central portion and the metal wires, whereby an electric resistance is small when the number of the contact portions 44a is larger and hence the current driving ability of the transistors 42a connected to the bit lines 8 arranged on the ends in a plurality of the bit lines 8 can be easily smaller than the current driving ability of the transistors 42a connected to the bit lines 8 arranged on the central portion.

According to the second embodiment, as hereinabove described, the number of the contact portions 44a connecting either the source regions or the drain regions of the transistors 42a and the metal wires 41 is gradually reduced from the bit lines 8 arranged on the central portion toward the bit lines 8 arranged on the ends in each eight bit lines, whereby an electric resistance is gradually increased from the bit lines 8 arranged on the central portion toward the bit lines 8 arranged on the ends. Thus, the current driving ability of the transistors 42a can be gradually reduced from the bit lines 8 arranged on the central portion toward the bit lines 8 arranged on the ends.

The remaining effects of the second embodiment are similar to those of the aforementioned first embodiment.

### Third Embodiment

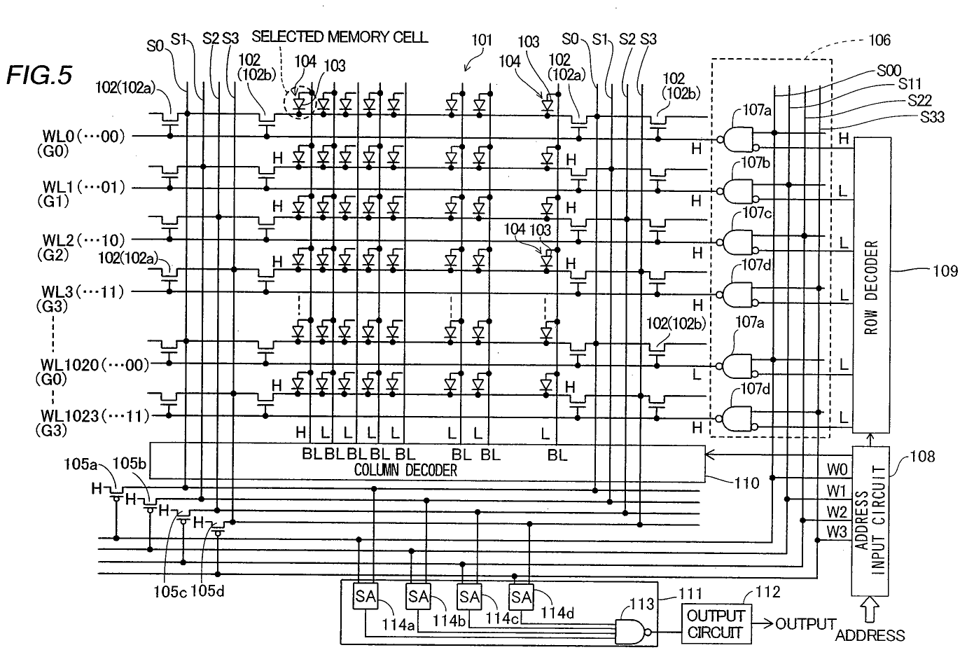

In a crosspoint diode ROM according to a third embodiment, a plurality of word lines WL and a plurality of bit lines BL are arranged in a memory cell array 101 to intersect with each other, as shown in FIG. 5. 1024 word lines WL are arranged in the memory cell array 101, and an address having a plurality of digits consisting of bits including “0” and “1” is allocated to each of the 1024 word lines WL. While serial numbers 0 to 1023 are sequentially assigned to the 1024 word lines WL, FIG. 5 illustrates only the word lines WL having the serial numbers 0 to 3, 1020 and 1023 in the 1024 word lines WL.

The 1024 word lines WL are classified into four word line groups G0 to G3 each including 256 word lines WL. More specifically, the first word line group GO includes word lines WL having addresses with lower digits (bits) (0,0) while the second word line group G1 includes word lines WL having addresses with lower digits (bits) (0,1). The third word group G2 includes word lines WL having addresses with lower digits (bits) (1,0) while the fourth word group G3 includes word lines WL having addresses with lower digits (bits) (1,1).

The gate electrodes of a prescribed number of selection transistors 102 are connected to each word line WL at prescribed intervals. The selection transistors 102 are examples of the “first transistors” in the present invention. Each selection transistor 102 is constituted by a pair of n-channel transistors 102a and 102b.

A plurality of memory cells 104 each including a diode 103 are provided in the memory cell array 101. The plurality of memory cells 104 are arranged in the form of a matrix along the plurality of word lines WL and the plurality of bit lines BL respectively, while a prescribed number of such memory cells 104 are connected to each word line WL through the corresponding selection transistor 102. More specifically, the cathodes of the prescribed number of diodes 103 are connected to the drain regions of the n-channel transistors 102a and 102b constituting the corresponding selection transistor 102. The anodes of the diodes 103 of prescribed memory cells 104 (holding data “1”) included in the plurality of memory cells 4 are connected to the corresponding bit lines BL, while the anodes of the diodes 103 of the remaining memory cells 104 (holding data “0”) are not connected to the corresponding bit lines BL. In the crosspoint diode ROM, the data held in each memory cell 104 is determined as “0” or “1” depending on whether or not the anode of the diode 103 of this memory cell 104 is connected to the corresponding bit line BL.

P-channel transistors 105a to 105d are arranged one by one for four source lines S0 to S3 respectively. More specifically, the p-channel transistor 105a has a drain connected to the source line S0 and a gate connected to another source line S00. The p-channel transistor 105b has a drain connected to the source line S1 and a gate connected to another source line S11. The p-channel transistor 105c has a drain connected to the source line S2 and a gate connected to another source line S22. The p-channel transistor 105d has a drain connected to the source line S3 and a gate connected to another source line S33. The sources of the p-channel transistors 105a to 105d are supplied with high-level signals.

The word line control circuit 106 for controlling the potentials of the word lines WL is provided between the plurality of word lines WL and a row decoder 109. This word line control circuit 106 is constituted by the four source lines S00 to S33 and a plurality of two-input NAND circuits 107a to 107d provided in correspondence to the four source lines S00 to S33 respectively. The two-input NAND circuits 107a are arranged one by one for the word lines WL (having addresses with lower digits (bits) (0,0)) included in the first word line group G0 corresponding to the first source line S00 respectively. The two-input NAND circuit 107b are arranged one by one for the word lines WL (having addresses with lower digits (bits) (0,1)) included in the second word line group G1 corresponding to the second source line S11 respectively. The two-input NAND circuits 107c are arranged one by one for the word lines WL (having addresses with lower digits (bits) (1,0)) included in the third word line group G2 corresponding to the third source line S22 respectively. The two-input NAND circuit 107d are arranged one by one for the word lines WL (having addresses with lower digits (bits) (1,1)) included in the fourth word line group G3 corresponding to the fourth source line S33 respectively.

First input terminals of the two-input NAND circuits 107a corresponding to the first word line group G0 are connected to the source line S00, while first input terminals of the two-input NAND circuits 107b corresponding to the second word line group G1 are connected to the source line S11. First input terminals of the two-input NAND circuits 107c corresponding to the third word line group G2 are connected to the source line S22, while first input terminals of the two-input NAND circuits 107d corresponding to the fourth word line group G3 are connected to the source line S33. Second input terminals of the two-input NAND circuits 107a to 107d are connected to corresponding output terminals of the row decoder 109 through inverter circuits respectively. Output terminals of the two-input NAND circuits 107a to 107d are connected to the corresponding word lines WL respectively.

When a prescribed word line WL is selected in the crosspoint diode ROM, the row decoder 109 supplies a high-level signal to the source line, included in the source lines S00 to S33, corresponding to the word line group (G0 in the third embodiment) including the selected word line WL. On the other hand, the row decoder 109 supplies low-level signals to the source lines, included in the source lines S00 to S33, corresponding to the remaining three word line groups (G1 to G3 in the third embodiment) not including the selected word line WL. The source lines S00 to S33 are supplied with signals W0 to W3 respectively.

An address input circuit 108, the row decoder 109, a column decoder 110, a data determination circuit 111 and an output circuit 112 are provided outside the memory cell array 101. The address input circuit 108 has a function of supplying address data to the row decoder 109 and the column decoder 110 in response to a prescribed address externally received therein.

The column decoder 110 has a function of supplying signals having prescribed potentials to the bit lines BL connected thereto. More specifically, the column decoder 110 is so formed as to select a prescribed bit line BL on the basis of the address data supplied from the address input circuit 108, for supplying a high-level signal to the selected bit line BL while supplying low-level signals to the nonselected bit lines BL.

The data determination circuit 111 has a function of determining the potential of data (signal) read from a selected memory cell 104 and supplying a signal responsive to the result of this determination to the output circuit 112. More specifically, the data determination circuit 111 supplies a low-level signal to the output circuit 112 when the data held in the selected memory cell 104 is at a high level, while supplying a high-level signal to the output circuit 112 when the data held in the selected memory cell 104 is at a low level. The output circuit 112 has a function of outputting a signal in response to the signal output from the data determination circuit 111. More specifically, the output circuit 112 outputs a high-level signal when the data determination circuit 111 outputs a low-level signal, while outputting a low-level signal when the data determination circuit 111 outputs a high-level signal.

The data determination circuit 111 includes a four-input NAND circuit 113 and sense amplifiers 114a to 114d. The four-input NAND circuit 113 has an input terminal connected to output terminals of the sense amplifiers 114a to 114d and an output terminal connected to the output circuit 112. The sense amplifiers 114a to 114d have first input terminals connected with the source lines S00 to S33 respectively and second input terminals connected with the source lines S0 to S3 respectively. The sense amplifiers 114a to 114d output high-level signals to the input terminal of the four-input NAND circuit 113 when the first input terminals thereof are supplied with low-level signals, while outputting high- or low-level signals to the input terminal of the four-input NAND circuit 113 in response to signals from the second input terminals when the first input terminals thereof are supplied with high-level signals.

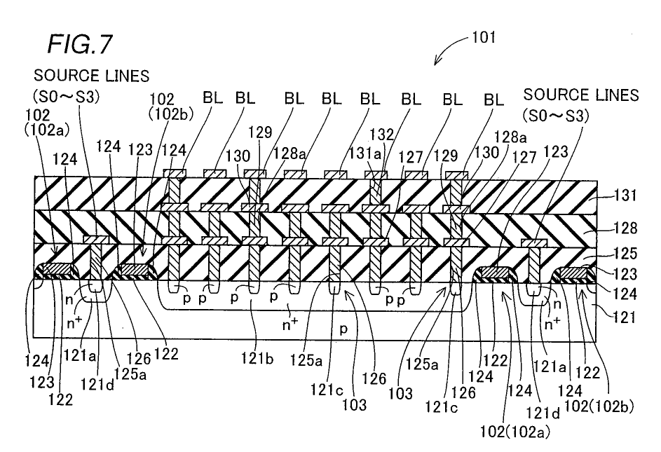

In the aforementioned memory cell array 101, n⁺-type impurity regions 121a and 121b having functions as source regions and drain regions of the selection transistors 102 are formed on an upper surface of a p-type silicon substrate 121, as shown in FIG. 7. The impurity regions 121b also have functions as cathodes of the diodes 103. A plurality of p-type impurity regions 121c having functions as anodes of the diodes 103 are formed at prescribed intervals in each impurity region 121b of the silicon substrate 121. Each of the aforementioned diodes 103 is formed by the impurity region (cathode) 121b and the impurity region (anode) 121c. N-type contact regions 121d are formed on regions where the impurity regions 121a and after-mentioned plugs 126 are in contact with each other. According to the third embodiment, distances of the impurity regions 121b from the cathodes of the diodes 103 under the bit lines BL arranged on the ends in the plurality of bit lines BL to either the source regions or the drain regions of the selection transistors 102 are shorter than the distances of the impurity regions 121b from the cathodes of the diodes 103 under the bit lines BL arranged on the central portions in the plurality of bit lines BL to either the source regions or the drain regions of the selection transistors 102. As the distances of the impurity regions 121b from the cathodes of the diodes 103 to either the source regions or the drain regions of the selection transistors 102 are longer, an electric resistance from the cathodes to either the source regions or the drain regions of the selection transistors 102 is increased.

Gate electrodes 123 are formed on regions between the impurity regions 121a and the impurity regions 121b on the silicon substrate 121 through the gate insulating films 122. Side wall films 124 are formed on side surfaces of the gate insulating films 122 and the gate electrodes 123. The selection transistors 102 (n-channel transistors 102a and 102b) are formed by the impurity regions (source and drain regions) 121a and 121b, the gate insulating films 122 and the gate electrodes 123.

A first-layer interlayer dielectric film 125 is formed on the silicon substrate 121, to cover the selection transistors 102. Contact holes 125a are formed on regions of the first-layer interlayer dielectric film 125 corresponding to the impurity regions 121a (source regions of the selection transistors 102) and impurity regions 121c (anodes of the diodes 103). The plugs 126 are embedded in the contact holes 125a of the first-layer interlayer dielectric film 125. The source lines (S0 to S4) are formed on regions corresponding to the impurity regions 121a (source regions of the selection transistors 102) on the first-layer interlayer dielectric film 125 and are connected to the impurity regions 121a through the plugs 126. First connecting layers 127 are formed on regions corresponding to the impurity regions 121c (anodes of the diodes 103) on the first-layer interlayer dielectric film 125.

The second interlayer dielectric film 128 is formed on the first-layer interlayer dielectric film 125, to cover the connecting layers 127. The contact holes 128a are formed on regions of the second interlayer dielectric film 128 corresponding to the connecting layers 127. The plugs 129 are embedded in the contact holes 128a. The second connecting layers 130 are formed on regions corresponding to the plugs 129 on the second interlayer dielectric film 128.

A third interlayer dielectric film 131 is formed on the second interlayer dielectric film 128, to cover the connecting layers 130. Contact holes 131a are formed on prescribed regions of the third interlayer dielectric film 131 and plugs 132 are embedded in the contact holes 131a. The aforementioned plurality of bit lines BL are arranged on the third interlayer dielectric film 131 at prescribed intervals. The plurality of bit lines BL include those connected to the second connecting layers 130 (anodes of the diodes 103) through the plugs 132 and those not connected to the second connecting layers 130 (anodes of the diodes 103).

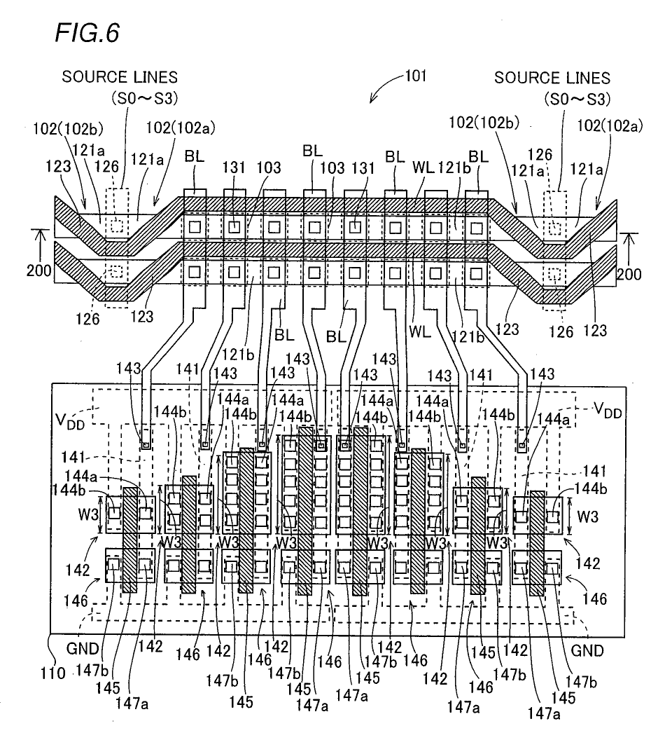

The plurality of word lines WL are arranged at prescribed intervals as shown in FIG. 6. The gate electrodes 123 are formed by partially bending the word lines WL to obliquely extend with respect to an extensional direction of the impurity regions 121b in plan view. The gate electrode 123 of each selection transistor 102a is arranged to intersect with the corresponding impurity region 121a on the region formed with the selection transistor 102a. The gate electrode 123 of each selection transistor 102b is arranged to intersect with the corresponding impurity region 121a on the region formed with the selection transistor 102b.

As shown in FIG. 6, a plurality of the bit lines BL have first ends connected to the transistors 142 for driving the bit lines BL through metal wires 141. The transistors 142 are examples of the “second transistors” or the “switching elements” in the present invention. The bit lines BL and the metal wires 141 are electrically connected to each other through contact portions 143. The metal wires 141 and either the source regions or the drain regions of the transistors 142 are electrically connected to each other through contact portions 144a. Either the source regions or the drain regions of the transistors 142 are connected to a power supply V_{DD} through contact portions 144b. According to the third embodiment, gate widths W3 of the transistors 142 connected to the bit lines BL arranged on the central portions in the plurality of bit lines BL are formed to be smaller than gate widths W3 of the transistors 142 driving the bit lines BL arranged on the ends. Thus, the driving ability of the transistors 142 driving the bit lines BL arranged on the ends in the plurality of bit lines BL is smaller than the driving ability of the transistors 142 driving the bit lines BL arranged on the central portions in the plurality of bit lines BL due to the smaller gate widths W3.

More specifically, according to the third embodiment, the gate widths W3 of the transistors 142 are gradually reduced from the bit lines BL arranged on the central portions in the plurality of bit lines toward the bit lines BL arranged on the ends. Thus, the driving ability of the bit lines BL is gradually reduced from the bit lines BL arranged on the central portions to the bit lines BL arranged on the ends.

The transistors 146 having common gate electrodes 145 with the transistors 142 are provided adjacent to the transistors 142 respectively. Either the source regions or the drain regions of the transistors 146 are connected to the metal wires 141 through contact portions 147a, while either the drain regions or the source regions thereof are grounded through contact portions 147b.

According to the third embodiment, as hereinabove described, the driving ability of the bit lines BL arranged on the ends in the plurality of bit lines BL is rendered low while the driving ability of the bit lines BL arranged on the central portions in the plurality of bit lines BL is rendered high, whereby the low driving ability of the bit lines BL can inhibit a large current from flowing in the source lines even when the distances of the impurity regions 121b between the source lines and the cathodes of the diodes 103 are short and the resistance thereof is small. Thus, increase in current consumption (power consumption) can be suppressed. It is possible to suppress increase in the time required for reducing the potentials of the source lines up to potentials where the sense amplifiers 114a to 114d can detect that a current does not flow, when accessing address, where a cell current does not flow, from a state of higher potentials of the source lines, and hence increase in the access time of the memory cells 104 can be suppressed.

According to the third embodiment, as hereinabove described, the driving ability of the bit lines BL is gradually reduced from the bit lines BL arranged on the central portions toward the bit lines BL arranged on the ends in the plurality of bit lines BL, whereby the driving ability of the bit lines BL is reduced from the central portions with a large resistance and a long distance of the impurity regions 121b between the source lines and the cathodes of the diodes 103 toward the ends with a small resistance and short distance, and hence the difference between the quantities of current flowing in the respective bit lines BL can be reduced. Thus, difference of the cell current flowing in the memory cell array 101 can be reduced as a whole.

According to the third embodiment, as hereinabove described, the distances of the impurity regions 121b from the cathodes of the diodes 103 under the bit lines BL arranged on the ends in the plurality of the bit lines BL to either the source regions or the drain regions of the selection transistors 102 are shorter than the distances of the impurity regions 121b from the cathodes of the diodes 103 under the bit lines BL arranged on the central portions in the plurality of bit lines BL to either the source regions or the drain regions of the selection transistors 102. An electric resistance varies depending on the distances of the impurity regions 121b, whereby a current flowing from the bit lines BL arranged on the ends in the plurality of the bit lines BL to the selection transistors 102 is increased while a current flowing from the bit lines BL arranged on the central portions in the plurality of the bit lines BL to the selection transistors 102 is reduced.

According to the third embodiment, as hereinabove described, the gate widths W3 of the transistors 142 driving the bit lines BL arranged on the ends in the plurality of bit lines BL are smaller than the gate widths W3 of the transistors 142 driving the bit lines BL arranged on the central portions, whereby the driving ability of the transistors 142 driving the bit lines BL arranged on the ends in a plurality of the bit lines BL can be easily rendered smaller than the driving ability of the transistors 142 driving the bit lines BL arranged on the central portions since an electric resistance is larger when the gate width W3 is small.

According to the third embodiment, as hereinabove described, the gate widths W3 of the transistors 142 are gradually reduced from the bit lines BL arranged on the central portions toward the bit lines BL arranged on the end in the plurality of bit lines BL, whereby an electric resistance is increased as the gate widths W3 is gradually reduced, and hence the driving ability of the transistors 142 can be gradually reduced from the bit lines BL arranged on the central portions toward the bit lines BL arranged on the ends in the plurality of bit lines BL.

### Fourth Embodiment

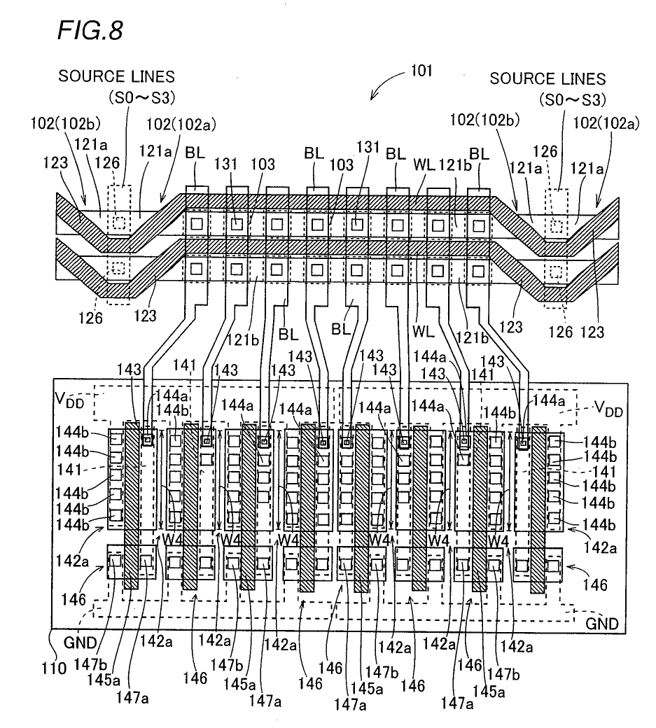

In a crosspoint diode ROM according to a fourth embodiment, a plurality of bit lines BL have first ends connected to transistors 142a through metal wires 141 respectively as shown in FIG. 8, similarly to the aforementioned third embodiment. The transistors 42a all have the same gate widths W4 dissimilarly to the third embodiment. The metal wires 141 and the transistors 142a are connected to each other through contact portions 143.

According to the fourth embodiment, in the number of contact portions 144a connecting either the source regions or the drain regions of the transistors 142a and the metal wires 41, the number of the contact portions 144a connecting either the source regions or the drain regions of the transistors 142a driving the bit lines 8 arranged on the ends in the plurality of bit lines BL and the metal wires 141 is smaller than the number of the contact portions 144a connecting either the source regions or the drain regions of the transistors 142a driving the bit lines BL arranged on the central portions and the metal wires 141.

More specifically, the number of the contact portions 144a connecting either the source regions or the drain regions of the transistors 142a and the metal wires 41 is gradually reduced from the bit lines BL arranged on the central portions toward the bit lines BL arranged on the ends in the plurality of bit lines BL.

Transistors 146 having common gate electrodes 145a are provided adjacent to the transistors 142a respectively.

The remaining structure of the fourth embodiment is similar to that of the aforementioned third embodiment.

According to the fourth embodiment, as hereinabove described, in the number of the contact portions 144a connecting either the source regions or the drain regions of the transistors 142a and the metal wires 141, the number of the contact portions 144a connecting either the source regions or the drain regions of the transistors 142a driving the bit lines BL arranged on the ends in the plurality of bit lines BL and the metal wires 141 is smaller than the number of the contact portions 144a connecting either the source regions or the drain regions of the transistors 142a driving the bit lines BL arranged on the central portions and the metal wires. Thus, an electric resistance is small when the number of the contact portions 144a is larger and hence the driving ability of the transistors 142a driving the bit lines BL arranged on the ends in the plurality of bit lines BL can be easily smaller than the driving ability of the transistors 42a driving to the bit lines BL arranged on the central portions.

According to the fourth embodiment, as hereinabove described, the number of the contact portions 144a connecting either the source regions or the drain regions of the transistors 142a and the metal wires 141 is gradually reduced from the bit lines BL arranged on the central portions toward the bit lines BL arranged on the ends in the plurality of bit lines, whereby an electric resistance is increased from the bit lines BL arranged on the central portions toward the bit lines BL arranged on the ends. Thus, the driving ability of the transistors 142a can be gradually reduced from the bit lines BL arranged on the central portions toward the bit lines BL arranged on the ends in the plurality of bit lines BL.

The remaining effects of the fourth embodiment are similar to those of the aforementioned third embodiment.

Although the present invention has been described and illustrated in detail, it is clearly understood that the same is by way of illustration and example only and is not to be taken by way of limitation, the spirit and scope of the present invention being limited only by the terms of the appended claims.

For example, the present invention is applied to the crosspoint diode ROM in each of the aforementioned first to fourth embodiments, the present invention is not restricted to this but is also widely applicable to a memory comprising memory cells including diodes other than the crosspoint diode ROM.

While the current driving ability of the transistors connected to the bit lines are changed by changing the gate widths of the transistors connected to the bit lines and the number of the contact portions in each of the aforementioned first to fourth embodiments, the present invention is not restricted to this but the current driving ability of the transistors connected to the bit lines may be changed by changing impurity concentrations of the source or drain regions of the transistors connected to the bit lines for the respective transistors. Alternatively, the current driving ability of the transistors connected to the bit lines may be changed by changing sizes of regions where impurities of the source or drain regions of the transistors connected to the bit lines are implanted. Alternatively, gate lengths of the transistors connected to the bit lines may be changes or resistances between the transistors connected to the bit lines and the bit lines may be provided.

While the plugs and the pad layers connecting the word lines and the impurity regions are arranged for each eight bit lines in each of the aforementioned first and second embodiments, the present invention is not restricted to this but the plugs and the pad layers connecting the word lines and the impurity regions may be arranged for a prescribed number, other than 8, of bit lines.

What is claimed is:

1. A memory comprising:
a plurality of word lines;
a plurality of bit lines so arranged as to intersect with said plurality of word lines;
a plurality of memory cells arranged on positions where said word lines and said bit lines intersect with each other respectively; and
selection circuits connected to said bit lines, wherein
the current driving ability of said selection circuits is different depending on positions where said bit lines are arranged.

2. The memory according to claim 1, wherein
the current driving ability of said selection circuit connected to said bit line arranged on an end in said plurality of bit lines is smaller than the current driving ability of said selection circuit connected to said bit line arranged on a central portion.

3. The memory according to claim 2, wherein
the current driving ability of said selection circuits connected to said bit lines is gradually reduced from said bit line arranged on the central portion toward said bit line arranged on the end in said plurality of bit lines.

4. The memory according to claim 2, further comprising;
impurity regions so arranged as to extend along an extensional direction of said word lines; and
first metal wires electrically connecting said word lines and said impurity regions at a prescribed interval, wherein
said bit lines are arranged between said first metal wires at a prescribed interval, and
the current driving ability of said selection circuit connected to said bit line arranged on the end in said plurality of bit lines arranged between said first metal wires is smaller than the current driving ability of said selection circuit connected to said bit line arranged on the central portion.

5. The memory according to claim 4, wherein
said plurality of memory cells includes diodes respectively, and
said impurity regions constitutes common cathodes of a plurality of said diodes included in said plurality of memory cells.

6. The memory according to claim 2, wherein
said selection circuits are constituted by transistors, and
the gate width of said transistor connected to said bit line arranged on the end in said plurality of bit lines is smaller than the gate width of said transistor connected to said bit line arranged on the central portion.

7. The memory according to claim 6, wherein
the gate widths of said transistors connected to said bit lines are gradually reduced from said bit line arranged on the central portion toward said bit line arranged on the end in said plurality of bit lines.

8. The memory according to claim 2, wherein
said selection circuits are constituted by transistors,
further comprising second metal wires connecting either source regions or drain regions of said transistors and said bit lines, wherein
in the number of contact portions electrically connecting either said source regions or said drain regions of said transistors and said second metal wires, the number of said contact portions electrically connecting either said source region or said drain region of said transistor connected to said bit line arranged on the end in said plurality of bit lines and said second metal wire is smaller than the number of said contact portions electrically connecting either said source region or said drain region of said transistor connected to said bit line arranged on the central portion and said second metal wires.

9. The memory according to claim 8, wherein
the number of said contact portions electrically connecting either said source regions or said drain regions of said transistors connected to said bit lines and said second metal wires is gradually reduced from said bit line arranged on the central portion toward said bit line arranged on the end in said plurality of bit lines.

10. A memory comprising:
a plurality of word lines;
a plurality of bit lines so arranged as to intersect with said plurality of word lines;
first transistors connected to said plurality of word lines respectively and entering ON-states when corresponding said word lines are selected;
a plurality of memory cells including diodes having cathodes connected to either source regions or drain regions of said first transistors respectively;
a source line connected to either said source regions or said drain regions of said first transistors; and
a data determination circuit for determining data read from selected said memory cell, connected to said source line, wherein
the driving ability of said bit lines is different depending on positions where said bit lines are arranged.

11. The memory according to claim 10, wherein
said plurality of bit lines are arranged adjacent to each other at a prescribed interval, and
the driving ability of said bit line arranged on an end in said plurality of bit lines arranged adjacent to each other is smaller than the driving ability of said bit line arranged on a central portion.

12. The memory according to claim 11, wherein
the driving ability of said bit lines is gradually reduced from said bit line arranged on the central portion toward said bit line arranged on the end in said plurality of bit lines arranged adjacent to each other.

13. The memory according to claim 11, further comprising impurity regions provided adjacent to either said source regions or said drain regions of said first transistors and constituting common cathodes of said diodes included in said plurality of memory cells respectively, wherein
the distance of said impurity region from said cathode of said diode under said bit line arranged on the end in said plurality of bit lines to either said source region or said drain region of said first transistor is shorter than the distance of said impurity region from said cathode of said diode under said bit line arranged on the central portion in said plurality of bit lines to either said source region or said drain region of said first transistor.

14. The memory according to claim 11, further comprising second transistors arranged on first ends of said bit lines and driving said bit lines, wherein
the gate width of said second transistor driving said bit line arranged on the end in said plurality of said bit lines arranged adjacent to each other at said prescribed interval is smaller than the gate width of said second transistor driving said bit line arranged on the central portion.

15. The memory according to claim 14, wherein
the gate widths of said second transistors driving said bit lines respectively are gradually reduced from said bit line arranged on the central portion toward said bit line arranged on the end in said plurality of bit lines arranged adjacent to each other at said prescribed interval.

16. The memory according to claim 11, further comprising:
second transistors arranged on first ends of said bit lines and driving said bit lines; and
metal wires connecting either source regions or drain regions of said second transistors and said bit lines, wherein
in the number of contact portions electrically connecting either said source regions or said drain regions of said second transistors and said metal wires, the number of said contact portions electrically connecting either said source region or said drain region of said second transistor driving said bit line arranged on the end in said plurality of said bit lines arranged adjacent to each other at said prescribed interval and said metal wire is smaller than the number of said contact portions electrically connecting either said source region or said drain region of said second transistor driving said bit line arranged on the central portion and said metal wire.

17. The memory according to claim 16, wherein
the number of said contact portions electrically connecting either said source regions or said drain regions of said second transistors and said metal wires is gradually reduced from said bit line arranged on the central portion toward said bit line arranged on the end in said plurality of bit lines arranged adjacent to each other at said prescribed interval.

18. A memory comprising:
a plurality of word lines;
a plurality of bit lines so arranged as to intersect with said plurality of word lines;
a plurality of memory cells arranged on positions where said word lines and said bit lines intersect with each other respectively; and
a plurality of switching elements connected to said plurality of bit lines respectively, wherein
the driving ability of said switching elements is different depending on positions where said bit lines are arranged.
